(19) United States
(12) Patent Application Publication
(10) Pub. No.: US 2026/0188246 A1
(43) Pub. Date: Jul. 2, 2026

(54) DISPLAY APPARATUS INCLUDING NARROW BEZEL

(71) Applicant: LG Display Co., Ltd., Seoul (KR)

(72) Inventors: Soon Hwan HONG, Paju-si (KR); Hong Sik KIM, Paju-si (KR); Chang Soo KIM, Paju-si (KR)

(73) Assignee: LG Display Co., Ltd., Seoul (KR)

(21) Appl. No.: 19/315,159

(22) Filed: Aug. 29, 2025

(30) Foreign Application Priority Data
Dec. 31, 2024 (KR) 10-2024-0202652

(51) Int. Cl. G09G 3/3266; G09G 3/20; G09G 3/3233

(52) U.S. Cl. CPC G09G 3/3266; G09G 3/2092; G09G 3/3233; G09G 2300/0842; G09G 2300/0861; G09G 2310/08; G09G 2320/0223

(57) ABSTRACT

A display apparatus includes a first emission driver set disposed in a first display area of a display panel and configured to output an emission signal, needed for pixel driving, to a plurality of emission signal supply lines, a second emission driver set disposed in a second display area of the display panel and configured to output the emission signal, needed for pixel driving, to a plurality of emission signal supply lines, a plurality of first emission clock pair lines connected to the first emission driver set in the first display area, a plurality of second emission clock pair lines connected to the second emission driver set in the second display area, and a plurality of emission clock link lines connected to the plurality of first emission clock pair lines and the plurality of second emission clock pair lines in common, wherein 2-phase 4-pair emission clocks are input to the plurality of emission clock link lines in a 2-phase mode, and 4-phase 4-pair emission clocks are input to the plurality of emission clock link lines in a 4-phase mode.

### CROSS-REFERENCE TO RELATED APPLICATIONS

This application claims the benefit of the Korean Patent Application No. 10-2024-0202652 filed on Dec. 31, 2024, which is hereby incorporated by reference as if fully set forth herein.

### BACKGROUND

### Technical Field

The present disclosure relates to a display apparatus.

### Description of the Related Art

In display apparatuses, the demand for a narrow bezel where a width of a non-display area is narrow is increasing. To implement a narrow bezel, a gate driver in active area (GIA) type where gate drivers are distributed and disposed in a display area has been known.

However, in a conventional GIA type, an RC delay of a gate clock increases due to an overlap capacitance which occurs in a number of gate driver sets and clock lines connected thereto. When an RC load of a gate clock increases, a gate output may be distorted.

Such a problem severely occurs in a large-screen display apparatus.

### BRIEF SUMMARY

The present disclosure provides a display apparatus which may reduce the distortion of a gate output occurring in gate driver sets distributed and disposed in a display area.

AS embodied and broadly described herein, a display apparatus includes a first emission driver set disposed in a first display area of a display panel and configured to output an emission signal, needed for pixel driving, to a plurality of emission signal supply lines; a second emission driver set disposed in a second display area of the display panel and configured to output the emission signal, needed for pixel driving, to a plurality of emission signal supply lines; a plurality of first emission clock pair lines connected to the first emission driver set in the first display area; a plurality of second emission clock pair lines connected to the second emission driver set in the second display area; and a plurality of emission clock link lines connected to the plurality of first emission clock pair lines and the plurality of second emission clock pair lines in common, wherein 2-phase 4-pair emission clocks are input to the plurality of emission clock link lines in a 2-phase mode, and 4-phase 4-pair emission clocks are input to the plurality of emission clock link lines in a 4-phase mode.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram illustrating a display apparatus according to an embodiment of the present disclosure;

FIG. 2 is a schematic cross-sectional view of a display area of a display panel;

FIG. 3 is a diagram illustrating a pixel circuit and a driving timing thereof;

FIG. 4 is a diagram illustrating an arrangement example of gate driver sets based on a gate driver in active area (GIA) type;

FIG. 5 is an enlarged view of a region XY of FIG. 4;

FIG. 6 is a diagram illustrating an example of an emission unit circuit included in an emission driver set;

FIG. 7 is a diagram illustrating an example where emission unit circuits are distributed and disposed in four pixel rows included in a display area;

FIG. 8 is a diagram illustrating a comparison of a clock line position based on a gate in panel (GIP) type and a clock line position based on a GIA type;

FIG. 9 is a diagram illustrating a case where an output of an emission signal is distorted when an RC delay of an emission clock increases in a GIA type;

FIG. 10 is a diagram illustrating a configuration of a timing controller selectively outputting a 2-phase emission clock and a 4-phase emission clock, based on a mode selection signal;

FIG. 11 is a diagram illustrating a connection structure between emission units and emission clock link lines for selectively implementing a 2-phase mode and a 4-phase mode;

FIG. 12 is a diagram illustrating another connection structure between emission units and emission clock link lines for selectively implementing a 2-phase mode and a 4-phase mode;

FIG. 13 is a diagram illustrating a driving sequence of a 2-phase mode;

FIG. 14 is a diagram illustrating a driving sequence of a 4-phase mode; and

FIG. 15 is a diagram illustrating a case where an RC delay of an emission clock is reduced to prevent the distortion of a gate output in a 4-phase mode compared to a 2-phase mode.

### DETAILED DESCRIPTION

Hereinafter, exemplary embodiments of the present disclosure will be described in detail with reference to the accompanying drawings. In the specification, in adding reference numerals for elements in each drawing, it should be noted that like reference numerals already used to denote like elements in other drawings are used for elements wherever possible. In the following description, when the detailed description of the relevant known function or configuration is determined to unnecessarily obscure the important point of the present disclosure, the detailed description will be omitted.

Like reference numerals refer to like elements. Also, a thickness, a ratio, and a dimension of each element described herein are illustrated to be partially enlarged or reduced for convenience of effective description. A scale of each element illustrated in the drawings of the present disclosure may have a scale which differs from a real scale, for convenience of description, but is not limited to a scale illustrated in the drawings.

In the present disclosure, when an arbitrary element (or a region, a layer, a portion, etc.) is described as “being on”, “connected”, or “coupled”, this may denote that the arbitrary element may be directly connected/coupled to another element, or a third element may be disposed therebetween.

The term “and/or” may include all of one or more combinations capable of being defined by relevant elements.

Terms like a first and a second may be used to describe various elements, but the elements should not be limited by the terms. The terms may be used only as object for distinguishing an element from another element. For example, without departing from the spirit and scope of the inventive concept, a first element may be referred to as a second element, and similarly, the second element may be referred to as the first element. The terms of a singular form may include plural forms unless referred to the contrary.

The terms “under”, “below”, “on”, and “above” may be used to describe a correlation between elements illustrated in the drawings. The terms may be a relative concept and may be described with respect to a direction illustrated in the drawings. For example, unless “just” or “direct” is used, one or more other elements between two elements may be disposed. Spatially relative terms “below”, “beneath”, “lower”, “above”, and “upper” may be used herein for easily describing a relationship between one device or elements and other devices or elements as illustrated in the drawings. Therefore, for example, “under” and “lower” may be opposite to “on” and “upper” with respect to a first element.

It should be understood that spatially relative terms are terms including different orientations of elements in use or operation, in addition to the orientation illustrated in the drawings. For example, if a device in the drawings is turned over, elements described as being on the “below” or “beneath” sides of other elements may be placed on “above” sides of the other elements. Therefore, the exemplary term “lower” may include both orientations of “lower” and “upper”. Likewise, the exemplary term “above” or “upper” may include both orientations of “above” and “below”.

It should be understood that the meaning of “include,” “comprise,” “including,” or “comprising,” specifies a property, a region, a fixed number, a step, a process, an element and/or a component, but does not exclude other properties, regions, fixed numbers, steps, processes, elements and/or components.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other, or may be carried out together in co-dependent relationship.

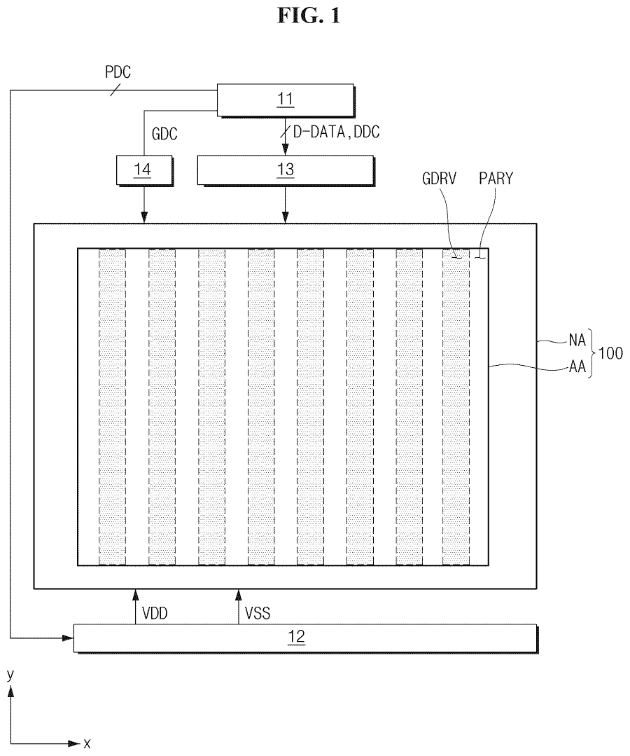

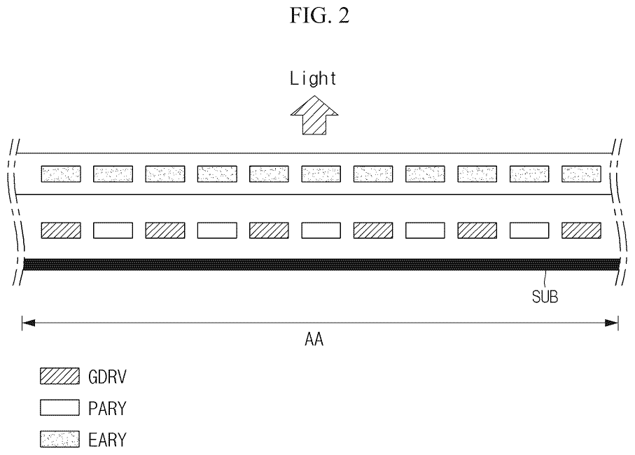

FIG. 1 is a block diagram illustrating a display apparatus according to an embodiment of the present disclosure. FIG. 2 is a schematic cross-sectional view of a display area of a display panel.

As illustrated in FIG. 1, the display apparatus according to an embodiment of the present disclosure may include a display panel 100, a timing controller 11, a power circuit 12, a data driver 13, a plurality of gate driver sets GDRV, and a level shifter 14.

The display panel 100 may include a display area (active area) AA and a non-display area (non-active area) NA. The non-display area NA may be disposed along an edge of the display panel 100, and the non-display area NA may be disposed outside the display area AA in the display panel 100.

The display area AA may display an image corresponding to image data D-DATA, and the non-display area NA may include a bezel region, which does not display an image, of the display panel 100.

As illustrated in FIG. 2, a plurality of pixel circuits PARY and a plurality of gate driver sets GDRV may be alternately arranged in the display area AA. In the display area AA, the pixel circuits PARY and the gate driver sets GDRV may be disposed under an emission array EARY and may at least partially overlap the emission array EARY. The emission array EARY may be implemented with a plurality of light emitting devices OLED. Light emitted from each of the light emitting devices OLED may be irradiated upward from a substrate SUB. One pixel may be implemented by a combination of one pixel circuit PARY and one light emitting device OLED. A plurality of pixels may be provided as a matrix type to configure a pixel array, in the display area AA.

The plurality of pixel circuits PARY and the plurality of gate driver sets GDRV may be alternately arranged in a first direction x (for example, a horizontal direction), and the gate driver sets GDRV may be arranged between the pixel circuits PARY. Each of the plurality of pixel circuits PARY and the plurality of gate driver sets GDRV may extend in a second direction y (for example, a vertical direction) intersecting the first direction x.

In the display area AA, a plurality of data lines extending in the first direction x may intersect a plurality of gate lines extending in the second direction y in the display area AA, and the pixel circuit PARY may be disposed in each of areas defined by intersections between the plurality of data lines and the plurality of gate lines. Each pixel circuit PARY may be connected to one data line and three gate lines. The three gate lines may include a first scan signal supply line, a second scan signal supply line, and an emission signal supply line.

In the display area AA, pixels adjacent to each other in the first direction x may configure a pixel row, and pixels adjacent to each other in the second direction y may configure a pixel column. A plurality of pixel rows and a plurality of pixel columns may be provided in the display area AA.

A plurality of pixels may be grouped to configure one unit pixel. The one unit pixel may be for implementing various colors. When a pixel group for color implementation is defined as a unit pixel, one unit pixel may be configured to include a red (R) pixel, a green (G) pixel, and a blue (B) pixel, but is not limited thereto and may be configured to include a red (R) pixel, a green (G) pixel, a blue (B), and a white (W) pixel.

The light emitting device OLED may include an anode electrode, a cathode electrode, and an organic compound layer formed therebetween. The organic compound layer may include a hole injection layer (HIL), a hole transport layer (HTL), an emission layer (EML), an electron transport layer (ETL), and an electron injection layer (EIL), but is not limited thereto. When a pixel current flows in the light emitting device OLED, a hole passing through the hole transport layer (HTL) and an electron passing through the electron transport layer (ETL) may move to the emission layer (EML) to generate an exciton, and thus, the emission layer (EML) may emit visible light. Also, the organic compound layer may be replaced with an inorganic compound layer.

A thin film transistor included in the pixel circuit PARY may be implemented to include low temperature polysilicon (LTPS) or oxide.

The timing controller 11 may supply digital image data D-DATA, transferred from a host system, to the data driver 13. The timing controller 11 may receive a timing signal such as a vertical synchronization signal, a horizontal synchronization signal, a data enable signal, and a dot clock from the host system to generate timing control signals for controlling operation timings of the data driver 13, the gate driver sets GDRV, and the power circuit 12.

The timing controller 11 may generate a gate timing control signal GDC for controlling the operation timings of the gate driver sets GDRV, a data timing control signal DDC for controlling the operation timing of the data driver 13, and a power timing control signal for controlling the operation timing of the power circuit 12.

The host system may be an application processor (AP) applied to mobile devices, wearable devices, and virtual/augmented reality (VR/AR) devices. Also, the host system may be a main board of television systems, set-top box, navigation systems, personal computers, and home theater systems, but is not limited thereto.

The data driver 13 may be connected to the plurality of pixels through the plurality of data lines. The data driver 13 may generate analog data voltages needed for driving of the pixels and may respectively supply the analog data voltages to the data lines.

The data driver 13 may sample and latch the digital image data D-DATA input from the timing controller 11 to generate parallel data, based on the data timing control signal DDC, a digital-to-analog converter (DAC) of the data driver 13 may map the digital image data D-DATA to gamma compensation voltages to generate data voltages, and the data driver 13 may respectively supply the data voltages to the pixels through the data lines. The data voltages may be analog voltages corresponding to image gray levels which are to be expressed in the pixels.

The data driver 13 may include a plurality of source driver integrated circuits (ICs). Each of the source driver ICs may include a shift register, a latch, the DAC, and an output buffer.

The gate driver sets GDRV may include a plurality of emission driver sets, a plurality of first scan driver sets, and a plurality of second scan driver sets.

The plurality of emission driver sets may be connected to the plurality of pixels through a plurality of emission signal supply lines. The plurality of emission driver sets may generate an emission signal needed for driving of the pixels and may supply the emission signal to the emission signal supply lines. The plurality of emission driver sets may be multiply connected to a plurality of positions of the emission signal supply line, and thus, a delay deviation of the emission signal based on a position may be reduced.

The plurality of first scan driver sets may be connected to a plurality of pixels through a plurality of first scan signal supply lines. The plurality of first scan driver sets may generate a first scan signal needed for driving of the pixels and may supply the first scan signal to the first scan signal supply lines. The plurality of first scan driver sets may be multiply connected to a plurality of positions of the first scan signal supply line, and thus, a delay deviation of the first scan signal based on a position may be reduced.

The plurality of second scan driver sets may be connected to a plurality of pixels through a plurality of second scan signal supply lines. The plurality of second scan driver sets may generate a second scan signal needed for driving of the pixels and may supply the second scan signal to the second scan signal supply lines. The plurality of second scan driver sets may be multiply connected to a plurality of positions of the second scan signal supply line, and thus, a delay deviation of the second scan signal based on a position may be reduced.

The level shifter 14 may be supplied with the gate timing control signal GDC from the timing controller 11 to convert a logic voltage level of the gate timing control signal GDC into a turn-on voltage level and a turn-off voltage level and may supply a level-converted gate timing control signal GDC to the gate driver sets GDRV. The gate timing control signal GDC may include emission clocks, first scan clocks, and second scan clocks.

The level shifter 14 may supply the emission clocks to the plurality of emission driver sets through emission clock lines disposed in the display area AA. The level shifter 14 may supply the first scan clocks to the plurality of first scan driver sets through first scan clock lines disposed in the display area AA. The level shifter 14 may supply the second scan clocks to the plurality of second scan driver sets through second scan clock lines disposed in the display area AA.

The emission clocks, the first scan clocks, and the second scan clocks may swing between a turn-on voltage and a turn-off voltage. The turn-on voltage may be set to a voltage which is greater than a threshold voltage of a transistor included in each of the gate driver sets GDRV, and the turn-off voltage may be set to a voltage which is less than the threshold voltage of the transistor. When the transistor included in each of the gate driver sets GDRV is a PMOS transistor, the turn-on voltage may be a gate low voltage VGL, and the turn-off voltage may be a gate high voltage VGH.

The power circuit 12 may increase or decrease an input power to generate a high-level pixel voltage VDD and a low-level pixel voltage VSS, based on the power timing control signal, and may supply the high-level pixel voltage VDD or the low-level pixel voltage VSS to the plurality of pixel circuits PARY and the plurality of gate driver sets GDRV.

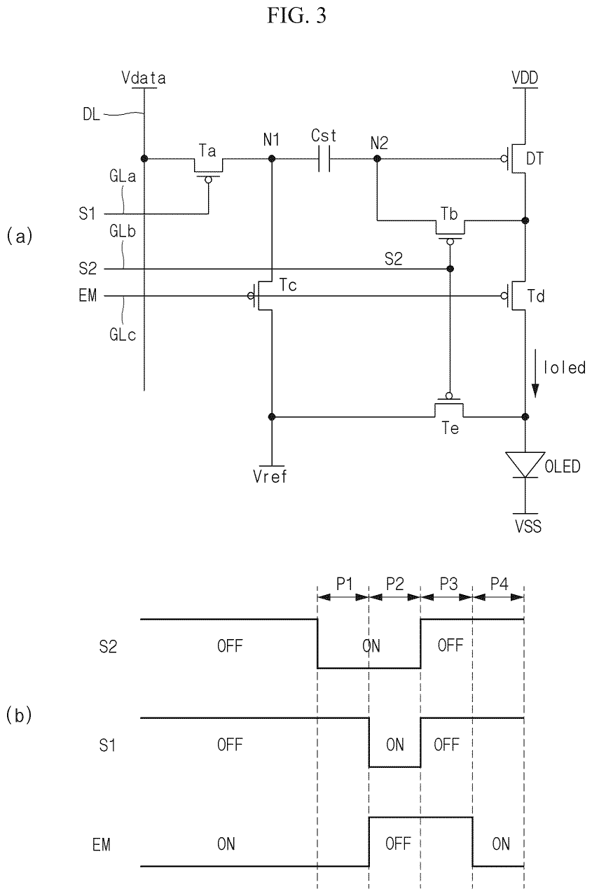

FIG. 3 is a diagram illustrating a pixel circuit and a driving timing thereof.

As illustrated in FIG. 3 (a), a pixel circuit according to an embodiment of the present disclosure may include Ta, Tb, Tc, Td, and Te transistors, a storage capacitor Cst, and a driving transistor DT and may be connected to a light emitting device OLED.

The Ta transistor may include a gate electrode receiving a first scan signal S1 through a first scan line GLa, a first electrode receiving a data voltage Vdata through a data line DL, and a second electrode connected to a first node N1. The Ta transistor may transfer the data voltage Vdata to the first node N1 in response to the first scan signal S1 of a turn-on level.

The storage capacitor Cst may be connected between the first node N1 and a second node N2 and may store a difference voltage between a voltage of the first node N1 and a voltage of the second node N2.

The driving transistor DT may include a gate electrode connected to the second node N2, a first electrode receiving a high-level driving voltage VDD, and a second electrode electrically connected to the light emitting device OLED. The driving transistor DT may be supplied with the high-level driving voltage VDD to generate a driving current corresponding to the voltage of the second node N2. A magnitude of the driving current may be differently generated based on the voltage of the second node N2.

The Tb transistor may include a gate electrode receiving a second scan signal S2 through a second scan line GLb, a first electrode connected to the second electrode of the driving transistor DT, and a second electrode connected to the second node N2. The Tb transistor may electrically connect the second electrode of the driving transistor DT to the second node N2 in response to the second scan signal S2 of a turn-on level. That is, while the Tb transistor is being turned on, the second electrode and the gate electrode of the driving transistor DT may be short-circuited therebetween, and thus, the driving transistor DT may operate like a diode.

The Tc transistor may include a gate electrode receiving an emission signal EM through an emission signal supply line GLc, a first electrode receiving a reference voltage Vref, and a second electrode connected to the first node N1. The Tc transistor may supply the reference voltage Vref to the first node N1 to initialize the first node N1, in response to the emission signal EM of a turn-on level.

The Td transistor may include a gate electrode receiving the emission signal EM, a first electrode connected to the driving transistor DT, and a second electrode connected to the light emitting device OLED. The Td transistor may supply the driving current, generated by the driving transistor DT, to the light emitting device OLED in response to the emission signal EM of a turn-on level.

The Te transistor may include a gate electrode receiving the second scan signal S2, a first electrode receiving the reference voltage Vref, and a second electrode connected to the anode electrode of the light emitting device OLED. The Te transistor may supply the reference voltage Vref to the anode electrode of the light emitting device OLED to initialize the anode electrode of the light emitting device OLED, in response to the second scan signal S2 of a turn-on level.

As illustrated in FIG. 3 (b), an operation sequence of the pixel circuit may include an initialization period P1, a programming period P2, a holding period P3, and an emission period P4.

In the initialization period P1, the second scan signal S2 and the emission signal EM may be input at a turn-on level, and the first node N1, the second node N2, and the anode electrode of the light emitting device OLED may be supplied with the reference voltage Vref and may thus be initialized.

In the programming period P2, a threshold voltage Vth of the driving transistor DT may be sampled, and the data voltage Vdata may be programmed in the second node N2. In detail, in the programming period P2, the first scan signal S1 and the second scan signal S2 may be input at a turn-on level, and thus, the data voltage Vdata may be supplied to the first node N1, and a voltage obtained by summating a driving voltage VDD and the threshold voltage Vth of the driving transistor DT may be supplied to the second node N2 and may be stored in the storage capacitor Cst.

In the holding period P3, the first and second scan signals S1 and S2 and the emission signal EM may be input at a turn-off level, and thus, the first and second nodes N1 and N2 connected to the storage capacitor Cst may be floated.

In the emission period P4, the emission signal EM may be input at a turn-on level, and thus, the driving transistor DT may generate the driving current to supply the driving current to the light emitting device OLED, based on a voltage level of the second node N2 connected to the storage capacitor Cst.

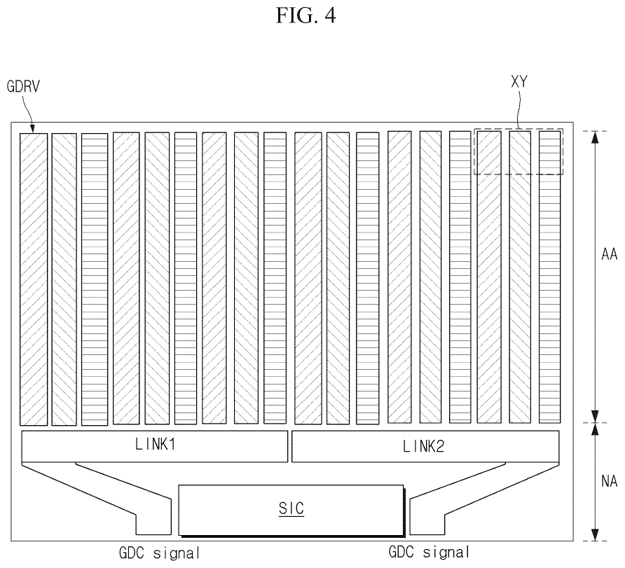

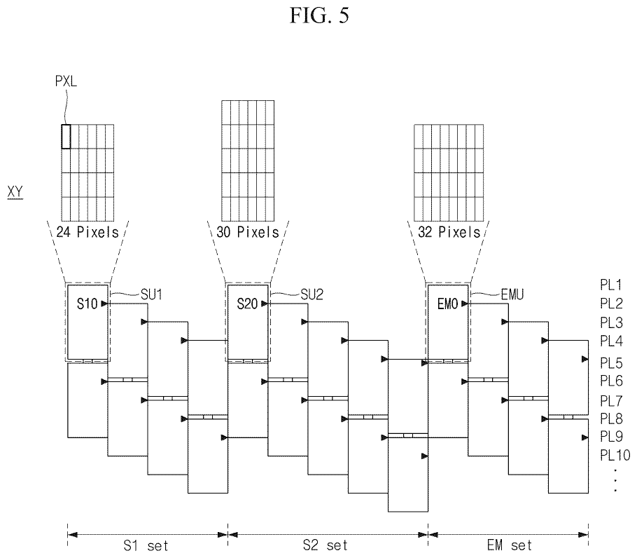

FIG. 4 is a diagram illustrating an arrangement example of gate driver sets based on a gate driver in active area (GIA) type. FIG. 5 is an enlarged view of a region XY of FIG. 4.

Referring to FIGS. 4 and 5, a plurality of gate driver sets GDRV may be distributed and disposed in a display area. The gate driver sets GDRV may include a plurality of first scan driver sets (hereinafter referred to as an S1 set), a plurality of second scan driver sets (hereinafter referred to as an S2 set), and a plurality of emission driver sets (hereinafter referred to as an EM set).

The S1 set may supply a first scan signal S1, where a phase thereof is sequentially shifted, to first scan signal supply lines of the display area. To this end, the S1 set may include first scan units SU1 equal to the number of first scan signal supply lines. Outputs S1O of the first scan units SU1 may be connected to the first scan signal supply lines. Each of the first scan units SU1 may include a plurality of circuit blocks. Circuit blocks configuring the first scan unit SU1 may be distributed and disposed in a pixel area of a 6 pixels*4 pixels (i.e., 24 pixels) size, but is not limited thereto.

The S2 set may supply a second scan signal S2, where a phase thereof is sequentially shifted, to second scan signal supply lines of the display area. To this end, the S2 set may include second scan units SU2 equal to the number of second scan signal supply lines. Outputs S2O of the second scan units SU2 may be connected to the second scan signal supply lines. Each of the second scan units SU2 may include a plurality of circuit blocks. Circuit blocks configuring the second scan unit SU2 may be distributed and disposed in a pixel area of a 6 pixels*5 pixels (i.e., 30 pixels) size, but is not limited thereto.

The EM set may supply an emission signal EM, where a phase thereof is sequentially shifted, to emission signal supply lines of the display area. To this end, the EM set may include emission units EMU equal to the number of emission signal supply lines. Outputs EMO of the emission units EMU may be connected to the emission signal supply lines. Each of the emission units EMU may include a plurality of circuit blocks. Circuit blocks configuring the emission unit EMU may be distributed and disposed in a pixel area of an 8 pixels*4 pixels (i.e., 32 pixels) size, but is not limited thereto.

In the display area, a plurality of S1 sets may be distributed and disposed, a plurality of S2 sets may be distributed and disposed, and a plurality of EM sets may be distributed and disposed. For example, the S1 sets, the S2 sets, and the EM sets may be repeatedly arranged in a set sequence of S1-S2-EM from the left of the display area. Gate driver sets GDRV of a first group may be disposed in a left display area managed by one source driver IC SIC, and gate driver sets GDRV of a second group may be disposed in a right display area.

The gate driver sets GDRV of the first group may be supplied with a gate timing control signal GDC through first link lines LINK1 included in a lower non-display area, and the gate driver sets GDRV of the second group may be supplied with the gate timing control signal GDC through second link lines LINK2 included in the lower non-display area. Because the first link lines LINK1 and the second link lines LINK2 are isolated from each other, a delay of the gate timing control signal GDC may be reduced.

Furthermore, in FIG. 5, “PL1 to PL10” may be pixel rows.

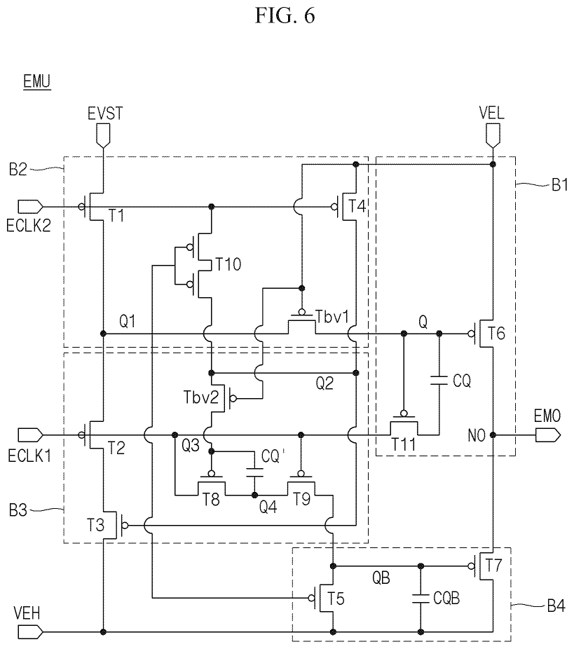

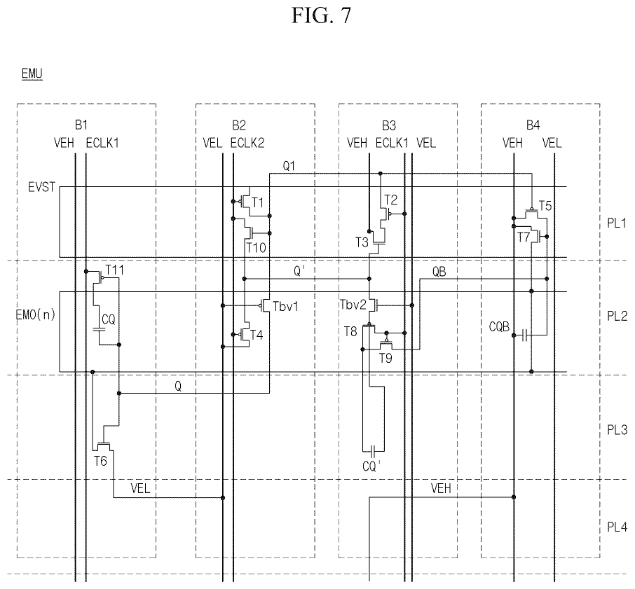

FIG. 6 is a diagram illustrating an example of an emission unit circuit included in an emission driver set. FIG. 7 is a diagram illustrating an example where emission unit circuits are distributed and disposed in four pixel rows included in a display area.

Referring to FIGS. 6 and 7, an emission unit EMU may be implemented as an edge trigger type. The emission unit EMU may be divided into a first block B1, a second block B2, a third block B3, and a fourth block B4. The emission unit EMU may be distributed and disposed in four pixel rows PL1 to PL4 included in a display area. The emission unit EMU may be distributed and disposed in a pixel area of an 8 pixels*4 pixels (i.e., 32 pixels) size, in four pixel rows PL1 to PL4.

The first block B1 may include a T6 transistor, a CQ capacitor, and a T11 transistor.

A gate electrode of the T6 transistor may be connected to a Q node, a first electrode thereof may be connected to a low-level driving voltage VEL, and a second electrode thereof may be connected to an output node NO. A gate electrode of the T11 transistor may be connected to the Q node, a first electrode thereof may be connected to the CQ capacitor, and a second electrode thereof may be connected to an input terminal of a first emission clock ECLK1. The CQ capacitor may be connected to the Q node and the first electrode of the T11 transistor.

The second block B2 may include a T1 transistor, a T4 transistor, a T10 transistor, and a Tbv1 transistor.

A gate electrode of the T1 transistor may be connected to an input terminal of a second emission clock ECLK2, a first electrode thereof may be connected to a start signal EVST or a front-end output (a carry signal), and a second electrode thereof may be connected to a Q1 node. A gate electrode of the T4 transistor may be connected to the input terminal of the second emission clock ECLK2, a first electrode thereof may be connected to the low-level driving voltage VEL, and a second electrode thereof may be connected to a Q2 node. A gate electrode of the T10 transistor may be connected to the Q1 node, a first electrode thereof may be connected to the input terminal of the second emission clock ECLK2, and a second electrode thereof may be connected to the Q2 node. A gate electrode of the Tbv1 transistor may be connected to the low-level driving voltage VEL, a first electrode thereof may be connected to the Q node, and a second electrode thereof may be connected to the Q1 node.

The third block B3 may include a T2 transistor, a T3 transistor, a T8 transistor, a T9 transistor, a Tbv2 transistor, and a CQ′ capacitor.

A gate electrode of the T2 transistor may be connected to the input terminal of the first emission clock ECLK1, a first electrode thereof may be connected to the Q1 node, and a second electrode thereof may be connected to a first electrode of the T3 transistor. A gate electrode of the T3 transistor may be connected to the Q2 node, the first electrode thereof may be connected to the second electrode of the T2 transistor, and a second electrode thereof may be connected to a high-level driving voltage VEH. A gate electrode of the T8 transistor may be connected to a Q3 node, a first electrode thereof may be connected to the input terminal of the first emission clock ECLK1, and a second electrode thereof may be connected to a Q4 node. A gate electrode of the T9 transistor may be connected to the input terminal of the first emission clock ECLK1, a first electrode thereof may be connected to a Q4 node, and a second electrode thereof may be connected to the QB node. More specifically, the second electrode of the T9 transistor may be connected to the high-level driving voltage VEH via the T5 transistor included in the fourth block B4. A gate electrode of the Tbv2 transistor may be connected to the low-level driving voltage VEL, a first electrode thereof may be connected to the Q2 node, and a second electrode thereof may be connected to the Q3 node. The CQ′ capacitor may be connected to the Q3 node and the Q4 node.

The fourth block B4 may include a T5 transistor, a T7 transistor, and a CQB capacitor.

A gate electrode of the T5 transistor may be connected to the Q1 node, a first electrode thereof may be connected to the QB node, and a second electrode thereof may be connected to the low-level driving voltage VEL. A gate electrode of the T7 transistor may be connected to the QB node, a first electrode thereof may be connected to the output node NO, and a second electrode thereof may be connected to the high-level driving voltage VEH. The CQB capacitor may be connected to the high-level driving voltage VEH and the QB node.

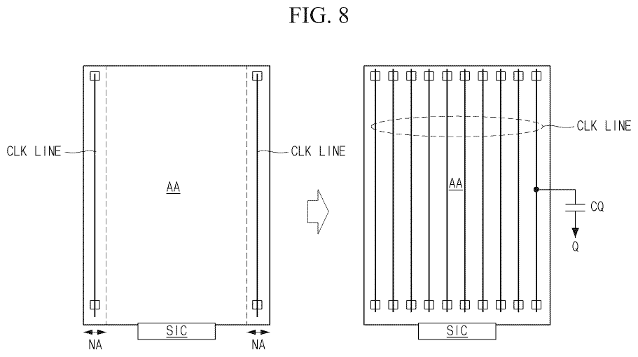

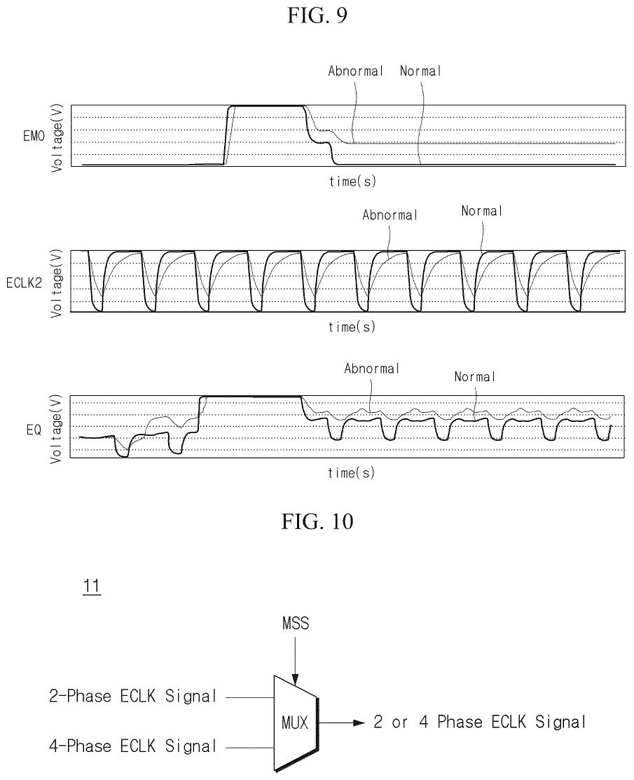

FIG. 8 is a diagram illustrating a comparison of a clock line position based on a gate in panel (GIP) type and a clock line position based on a GIA type. FIG. 9 is a diagram illustrating a case where an output of an emission signal is distorted when an RC delay of an emission clock increases in a GIA type.

According to a conventional GIP type, as in left of FIG. 8, clock lines for a gate output (for example, a scan signal and an emission signal) may be disposed in a left non-display area NA and a right non-display area NA. Gate driver sets may be disposed in the left non-display area NA and the right non-display area NA.

On the other hand, according to a GIA type of the present disclosure, because gate driver sets are distributed and disposed in a display area, as in right of FIG. 8, a plurality of clock lines for a gate output may be distributed and disposed in a display area AA.

The GIA type may be relatively far greater in load of a clock signal than the GIP type. Referring to FIGS. 6 and 9, an emission clock ECLK2 may affect the Q node EQ, and thus, when a load of the emission clock ECLK2 increases, an emission output EMO may be distorted.

In detail, when the emission clock ECLK2 is delayed by an increase in load, a voltage of the emission clock ECLK2 may not reach a level capable of turning on the T1 transistor, and thus, a voltage of the Q node EQ may increase. Therefore, a coupling effect based on a connection node between the CQ capacitor and the T11 transistor may decrease. As a result, the T6 transistor may not be fully turned on, and due to this, a voltage of the emission output EMO may abnormally increase. To reduce the distortion of the emission output EMO, a method of reducing a delay of an emission clock may be needed.

FIG. 10 is a diagram illustrating a configuration of a timing controller selectively outputting a 2-phase emission clock and a 4-phase emission clock, based on a mode selection signal.

Referring to FIG. 10, a timing controller 11 may selectively implement a 2-phase mode and a 4-phase mode, based on a mode selection signal MSS. The mode selection signal MSS may be user input information input from the outside, but is not limited thereto. The mode selection signal MSS may be automatically changed based on an attribute of an input image displayed on a screen, or may be automatically changed at every certain period.

The timing controller 11 may include a multiplexer circuit MUX. The multiplexer circuit MUX may output 2-phase 4-pair emission clocks to implement the 2-phase mode, based on the mode selection signal MSS of a first logic level. The multiplexer circuit MUX may output 4-phase 4-pair emission clocks to implement the 4-phase mode, based on the mode selection signal MSS of a second logic level which differs from the first logic level.

Each of the 4-phase 4-pair emission clocks may be greater in on pulse width and longer pulse period than each of 2-phase 4-pair emission clocks. Accordingly, an RC load of each of emission clocks may be less in the 4-phase mode than the 2-phase mode.

On the other hand, the 2-phase mode may control an emission duty of an emission signal through pulse width modulation (PWM) driving, and thus, fine luminance control thereof may be relatively easier than the 4-phase mode.

The timing controller 11 may output the 4-phase 4-pair emission clocks in the 4-phase mode to prevent the distortion of an emission clock and may output the 2-phase 4-pair emission clocks in the 2-phase mode to implement fine luminance control.

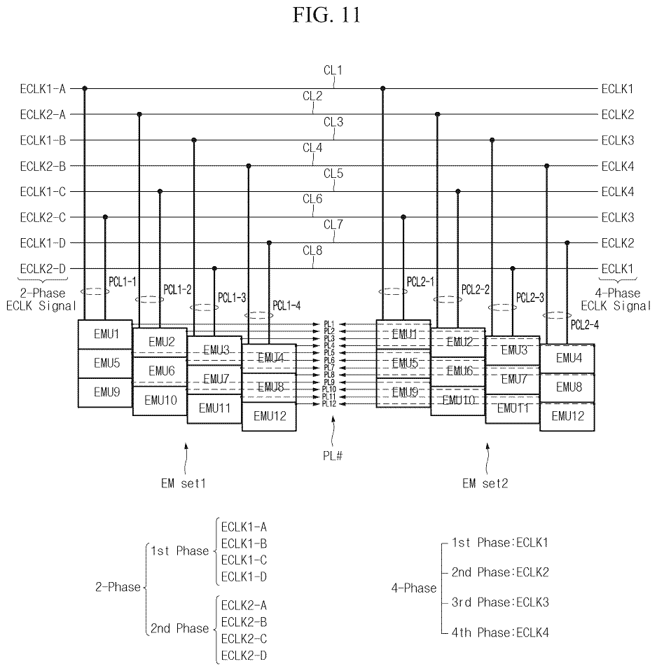

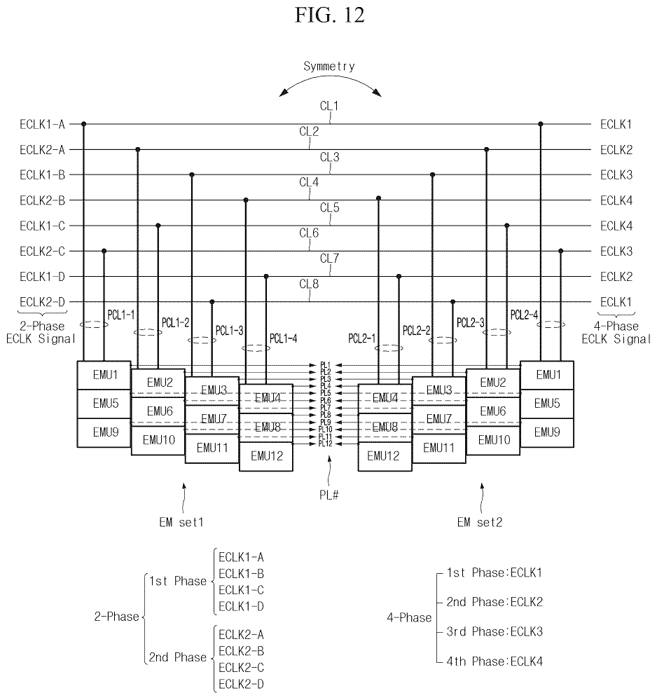

FIGS. 11 and 12 are diagrams illustrating various connection structures between emission units and emission clock link lines for selectively implementing the 2-phase mode and the 4-phase mode.

Referring to FIGS. 11 and 12, a plurality of EM sets in a display area may be disposed apart from each other with S1 and S2 sets (not shown) therebetween. The inventive concept is not limited to the number of EM sets. The inventive concept may be applied to two or more EM sets.

In detail, a first EM set may be disposed in a first display area of a display panel and may output an emission signal, needed for pixel driving, to a plurality of emission signal supply lines. First emission clock pair lines PCL1-1 to PCL1-4 may be connected to the first EM set in the first display area.

A second EM set may be disposed in a second display area of the display panel and may output an emission signal, needed for pixel driving, to the plurality of emission signal supply lines. Second emission clock pair lines PCL2-1 to PCL2-4 may be connected to the second EM set in the second display area.

Emission units EMU1 to EMU12 included in the first EM set and emission units EMU1 to EMU12 included in the second EM set, as in FIG. 11, may be asymmetric with each other.

The emission units EMU1 to EMU12 included in the first EM set and the emission units EMU1 to EMU12 included in the second EM set, as in FIG. 12, may be axisymmetric with respect to a symmetric axis between the first EM set and the second EM set.

Emission clock link lines CL1 to CL8 may be connected to the first emission clock pair lines PCL1-1 to PCL1-4 and the second emission clock pair lines PCL2-1 to PCL2-4 in common.

In the 2-phase mode, the emission clock link lines CL1 to CL8 may receive 2-phase 4-pair emission clocks ECLK1-A, ECLK2-A, ECLk1-B, ECLK2-B, ECLK1-C, ECLK2-C, ECLK1-D, and ECLK2-D and may transfer the received 2-phase 4-pair emission clocks ECLK1-A, ECLK2-A, ECLK1-B, ECLK2-B, ECLK1-C, ECLK2-C, ECLK1-D, and ECLK2-D to the first emission clock pair lines PCL1-1 to PCL1-4 and the second emission clock pair lines PCL2-1 to PCL2-4. Each of the 2-phase 4-pair emission clocks ECLK1-A, ECLK2-A, ECLK1-B, ECLK2-B, ECLK1-C, ECLK2-C, ECLK1-D, and ECLK2-D may have an on pulse width of one horizontal period.

In the 4-phase mode, the emission clock link lines CL1 to CL8 may receive 4-phase 4-pair emission clocks ECLK1, ECLK2, ECLK3, ECLK4, ECLK4, ECLK3, ECLK2, and ECLK1 and may transfer the received 4-phase 4 -pair emission clocks ECLK1, ECLK2, ECLK3, ECLK4, ECLK4, ECLK3, ECLK2, and ECLK1 to the first emission clock pair lines PCL1-1 to PCL1-4 and the second emission clock pair lines PCL2-1 to PCL2-4. Each of the 4-phase 4-pair emission clocks ECLK1, ECLK2, ECLK3, ECLK4, ECLK4, ECLK3, ECLK2, and ECLK1 may have an on pulse width of two horizontal period.

### Description of Operation of 2-phase Mode

The 2-phase 4-pair emission clocks may include a 1-A emission clock ECLK1-A input to a first emission clock link line CL1, a 2-A emission clock ECLK2-A input to a second emission clock link line CL2 adjacent to the first emission clock link line CL1, a 1-B emission clock ECLK1-B input to a third emission clock link line CL3 adjacent to the second emission clock link line CL2, a 2-B emission clock ECLK2-B input to a fourth emission clock link line CL4 adjacent to the third emission clock link line CL3, a 1-C emission clock ECLK1-C input to a fifth emission clock link line CL5 adjacent to the fourth emission clock link line CL4, a 2-C emission clock ECLK2-C input to a sixth emission clock link line CL6 adjacent to the fifth emission clock link line CL5, a 1-D emission clock ECLK1-D input to a seventh emission clock link line CL7 adjacent to the sixth emission clock link line CL6, and a 2-D emission clock ECLK2-D input to an eighth emission clock link line CL8 adjacent to the seventh emission clock link line CL7.

The 1-A emission clock ECLK1-A, the 1-B emission clock ECLK1-B, the 1-C emission clock ECLK1-C, and the 1-D emission clock ECLK1-D may have the same first phase.

The 2-A emission clock ECLK2-A, the 2-B emission clock ECLK2-B, the 2-C emission clock ECLK2-C, and the 2-D emission clock ECLK2-D may have the same second phase. The second phase may be later or earlier than the first phase.

In the 2-phase mode, the first EM set may include first to fourth emission units EMU1 to EMU4 which generate emission outputs where phases thereof are sequentially delayed. In one embodiment, the emission clock pair lines PCL1-1 to PCL1-4 of the first to fourth emission units EMU1 to EMU4 each receive one light-emitting clock of the first phase and one emitting clock of the second phase from different emission clock link lines, and each emission clock link supplies the emitting clock input thereto to only one of the light-emitting clock pair lines PCL1-1 to PCL1-4.

The first emission unit EMU1 may be connected to the first and sixth emission clock link lines CL1 and CL6 through a 1-1 emission clock pair line PCL1-1 and may receive the 1-A emission clock ECLK1-A and the 2-C emission clock ECLK2-C to supply an emission output of the first phase to an emission signal supply line of a first pixel row PL1.

The second emission unit EMU2 may be connected to the second and fifth emission clock link lines CL2 and CL5 through a 1-2 emission clock pair line PCL1-2 and may receive the 2-A emission clock ECLK2-A and the 1-C emission clock ECLK1-C to supply an emission output of the second phase, which is later than the first phase, to an emission signal supply line of a second pixel row PL2 adjacent to the first pixel row PL1.

The third emission unit EMU3 may be connected to the third and eighth emission clock link lines CL3 and CL8 through a 1-3 emission clock pair line PCL1-3 and may receive the 1-B emission clock ECLK1-B and the 2-D emission clock ECLK2-D to supply an emission output of a third phase, which is later than the second phase, to an emission signal supply line of a third pixel row PL3 adjacent to the second pixel row PL2.

The fourth emission unit EMU4 may be connected to the fourth and seventh emission clock link lines CL4 and CL7 through a 1-4 emission clock pair line PCL1-4 and may receive the 2-B emission clock ECLK2-B and the 1-D emission clock ECLK1-D to supply an emission output of a fourth phase, which is later than the third phase, to an emission signal supply line of a fourth pixel row PL4 adjacent to the third pixel row PL3.

In the 2-phase mode, the second EM set may include first to fourth emission units EMU1 to EMU4 which generate emission outputs where phases thereof are sequentially delayed. In one embodiment, the emission clock pair lines PCL2-1 to PCL2-4 of the first to fourth emission units EMU1 to EMU4 each receive one light-emitting clock of the first phase and one emitting clock of the second phase from different emission clock link lines, and each emission clock link supplies the emitting clock input thereto to only one of the light-emitting clock pair lines PCL1-1 to PCL1-4.

The first emission unit EMU1 may be connected to the first and sixth emission clock link lines CL1 and CL6 through a 2-1 emission clock pair line PCL 2-1 and may receive the 1-A emission clock ECLK1-A and the 2-C emission clock ECLK2-C to supply an emission output of the first phase to the emission signal supply line of the first pixel row PL1.

The second emission unit EMU2 may be connected to the second and fifth emission clock link lines CL2 and CL5 through a 2-2 emission clock pair line PCL2-2 and may receive the 2-A emission clock ECLK2-A and the 1-C emission clock ECLK1-C to supply an emission output of the second phase, which is later than the first phase, to the emission signal supply line of the second pixel row PL2 adjacent to the first pixel row PL1.

The third emission unit EMU3 may be connected to the third and eighth emission clock link lines CL3 and CL8 through a 2-3 emission clock pair line PCL2-3 and may receive the 1-B emission clock ECLK1-B and the 2-D emission clock ECLK2-D to supply an emission output of the third phase, which is later than the second phase, to the emission signal supply line of the third pixel row PL3 adjacent to the second pixel row PL2.

The fourth emission unit EMU4 may be connected to the fourth and seventh emission clock link lines CL4 and CL7 through a 2-4 emission clock pair line PCL2-4 and may receive the 2-B emission clock ECLK2-B and the 1-D emission clock ECLK1-D to supply an emission output of the fourth phase, which is later than the third phase, to the emission signal supply line of the fourth pixel row PL4 adjacent to the third pixel row PL3.

### Description of Operation of 4-phase Mode

The 4-phase 4-pair emission clocks may include a first emission clock ECLK1 input to the first emission clock link line CL1, a second emission clock ECLK2 input to the second emission clock link line CL2 adjacent to the first emission clock link line CL1, a third emission clock ECLK3 input to the third emission clock link line CL3 adjacent to the second emission clock link line CL2, a fourth emission clock ECLK4 input to the fourth emission clock link line CL4 adjacent to the third emission clock link line CL3, a fourth emission clock ECLK4 input to the fifth emission clock link line CL5 adjacent to the fourth emission clock link line CL4, the third emission clock ECLK3 input to the sixth emission clock link line CL6 adjacent to the fifth emission clock link line CL5, the second emission clock ECLK2 input to the seventh emission clock link line CL7 adjacent to the sixth emission clock link line CL6, and the first emission clock ECLK1 input to the eighth emission clock link line CL8 adjacent to the seventh emission clock link line CL7.

The first emission clock ECLK1 may have the first phase, the second emission clock ECLK2 may have the second phase which is later than the first phase, the third emission clock ECLK3 may have the third phase which is later than the second phase, and the fourth emission clock ECLK4 may have the fourth phase which is later than the third phase.

In the 4-phase mode, the first EM set may include first to fourth emission units EMU1 to EMU4 which generate emission outputs where phases thereof are sequentially delayed. In one embodiment, two of the first to fourth emission units EMU1 to EMU4 receive one emission clock of the first phase and on emission clock of the third phase from different emission clock link lines through corresponding emission clock pair lines, while the other two emission units receive one emission clock of the second phase and one emission clock of the fourth phase from different emission clock link line through corresponding emission clock pair lines. Each emission clock connection line supplies the emission clock input thereto to only one of the emission clock pair lines PCL1-1 to PCL1-4.

The first emission unit EMU1 may be connected to the first and sixth emission clock link lines CL1 and CL6 through the 1 -1 emission clock pair line PCL1-1 and may receive the first emission clock ECLK1 and the third emission clock ECLK3 to supply an emission output of the first phase to the emission signal supply line of the first pixel row PL1.

The second emission unit EMU2 may be connected to the second and fifth emission clock link lines CL2 and CL5 through the 1-2 emission clock pair line PCL1-2 and may receive the second emission clock ECLK2 and the fourth emission clock ECLK4 to supply an emission output of the second phase, which is later than the first phase, to the emission signal supply line of the second pixel row PL2 adjacent to the first pixel row PL1.

The third emission unit EMU3 may be connected to the third and eighth emission clock link lines CL3 and CL8 through the 1-3 emission clock pair line PCL1-3 and may receive the third emission clock ECLK3 and the first emission clock ECLK1 to supply an emission output of the third phase, which is later than the second phase, to the emission signal supply line of the third pixel row PL3 adjacent to the second pixel row PL2.

The fourth emission unit EMU4 may be connected to the fourth and seventh emission clock link lines CL4 and CL7 through the 1-4 emission clock pair line PCL1-4 and may receive the fourth emission clock ECLK4 and the second emission clock ECLK2 to supply an emission output of the fourth phase, which is later than the third phase, to the emission signal supply line of the fourth pixel row PL4 adjacent to the third pixel row PL3.

In the 4-phase mode, the second EM set may include first to fourth emission units EMU1 to EMU4 which generate emission outputs where phases thereof are sequentially delayed. In one embodiment, two of the first to fourth emission units EMU1 to EMU4 receive one emission clock of the first phase and on emission clock of the third phase from different emission clock link lines through corresponding emission clock pair lines, while the other two emission units receive one emission clock of the second phase and one emission clock of the fourth phase from different emission clock link line through corresponding emission clock pair lines. Each emission clock connection line supplies the emission clock input thereto to only one of the emission clock pair lines PCL2-1 to PCL2-4.

The first emission unit EMU1 may be connected to the first and sixth emission clock link lines CL1 and CL6 through the 2-1 emission clock pair line PCL2-1 and may receive the first emission clock ECLK1 and the third emission clock ECLK3 to supply an emission output of the first phase to the emission signal supply line of the first pixel row PL1.

The second emission unit EMU2 may be connected to the second and fifth emission clock link lines CL2 and CL5 through the 2-2 emission clock pair line PCL2-2 and may receive the second emission clock ECLK2 and the fourth emission clock ECLK4 to supply an emission output of the second phase, which is later than the first phase, to the emission signal supply line of the second pixel row PL2 adjacent to the first pixel row PL1.

The third emission unit EMU3 may be connected to the third and eighth emission clock link lines CL3 and CL8 through the 2-3 emission clock pair line PCL2-3 and may receive the third emission clock ECLK3 and the first emission clock ECLK1 to supply an emission output of the third phase, which is later than the second phase, to the emission signal supply line of the third pixel row PL3 adjacent to the second pixel row PL2.

The fourth emission unit EMU4 may be connected to the fourth and seventh emission clock link lines CL4 and CL7 through the 2-4 emission clock pair line PCL2-4 and may receive the fourth emission clock ECLK4 and the second emission clock ECLK2 to supply an emission output of the fourth phase, which is later than the third phase, to the emission signal supply line of the fourth pixel row PL4 adjacent to the third pixel row PL3.

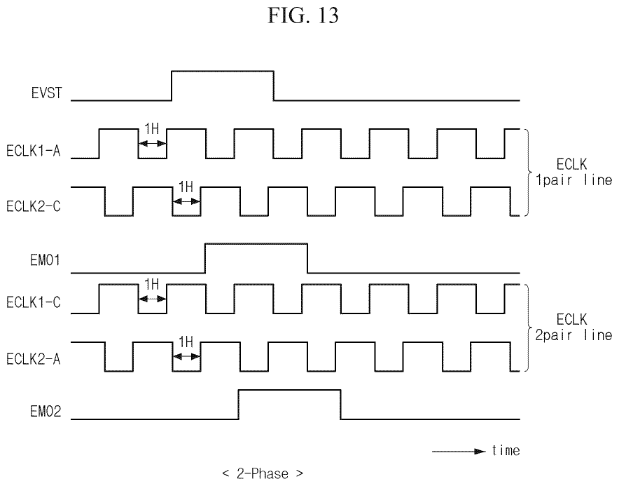

FIG. 13 is a diagram illustrating a driving sequence of the 2-phase mode.

Referring to FIG. 13, in the 2-phase mode, the first emission unit EMU1 may receive a 1-A emission clock ECLK1-A and a 2-C emission clock ECLK2-C to supply an emission output EMO1 of the first phase to the emission supply line of the first pixel row PL1. Each of the 1-A emission clock ECLK1-A and the 2-C emission clock ECLK2-C may have an on pulse width of one horizontal period 1H.

Referring to FIG. 13, in the 2-phase mode, the second emission unit EMU2 may receive a 2-A emission clock ECLK2-A and a 1-C emission clock ECLK1-C to supply an emission output EMO2 of the second phase, which is later than the first phase, to the emission supply line of the second pixel row PL2. Each of the 2-A emission clock ECLK2-A and the 1-C emission clock ECLK1-C may have an on pulse width of one horizontal period 1H.

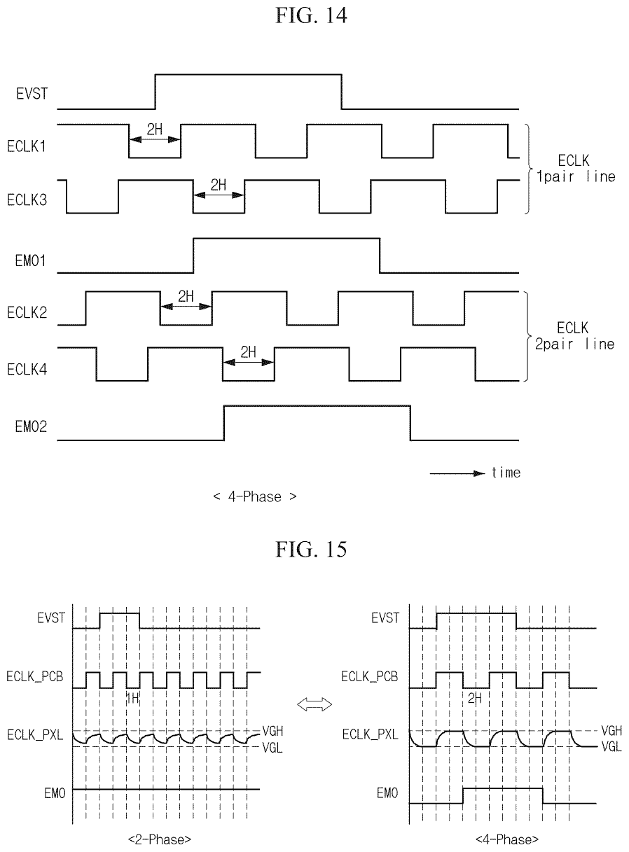

FIG. 14 is a diagram illustrating a driving sequence of the 4-phase mode.

Referring to FIG. 14, in the 4-phase mode, the first emission unit EMU1 may receive a first emission clock ECLK1 and a third emission clock ECLK3 to supply an emission output EMO1 of the first phase to the emission supply line of the first pixel row PL1. Each of the first emission clock ECLK1 and the third emission clock ECLK3 may have an on pulse width of two horizontal period 2H.

Referring to FIG. 14, in the 4-phase mode, the second emission unit EMU2 may receive a second emission clock ECLK2 and a fourth emission clock ECLK4 to supply an emission output EMO2 of the second phase, which is later than the first phase, to the emission supply line of the second pixel row PL2. Each of the second emission clock ECLK2 and the fourth emission clock ECLK4 may have an on pulse width of two horizontal period 2H.

FIG. 15 is a diagram illustrating a case where an RC delay of an emission clock is reduced to prevent the distortion of a gate output in the 4-phase mode compared to the 2-phase mode.

Referring to FIG. 15, because an on pulse width of an emission clock increases to two horizontal period 2H in the 4-phase mode compared to the 2-phase mode, a sufficient timing margin for enabling the emission clock to vary up to a target on voltage may be secured. Accordingly, in the 4-phase mode, an RC delay of the emission clock may decrease, thereby preventing the distortion of a gate output.

The display apparatus according to the embodiments of the present disclosure may include a clock line connection structure for selectively implementing a 2-phase mode and a 4-phase mode to reduce a delay of an emission clock, and thus, may decrease the distortion of a gate output occurring in gate driver sets distributed and disposed in a display area.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure including the following claims.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a first emission driver set disposed in a first display area of a display panel and configured to output an emission signal to a first plurality of emission signal supply lines;
a second emission driver set disposed in a second display area of the display panel and configured to output the emission signal to a second plurality of emission signal supply lines;
a plurality of first emission clock pair lines connected to the first emission driver set in the first display area;
a plurality of second emission clock pair lines connected to the second emission driver set in the second display area; and
a plurality of emission clock link lines connected to the plurality of first emission clock pair lines and the plurality of second emission clock pair lines in common,
wherein 2-phase 4-pair emission clocks are input to the plurality of emission clock link lines in a 2-phase mode, and
4-phase 4-pair emission clocks are input to the plurality of emission clock link lines in a 4-phase mode.

2. The display apparatus of claim 1, wherein an on pulse width of each of the 4-phase 4-pair emission clocks is greater than an on pulse width of each of the 2-phase 4-pair emission clocks.

3. The display apparatus of claim 1, wherein each of the 2-phase 4-pair emission clocks has an on pulse width of one horizontal period, and
each of the 4-phase 4-pair emission clocks has an on pulse width of two horizontal period.

4. The display apparatus of claim 1, further comprising a timing controller, the timing controller selectively outputting the 2-phase 4-pair emission clocks and the 4-phase 4-pair emission clocks based on a mode selection signal.

5. The display apparatus of claim 1, wherein the mode selection signal is automatically changed based on an attribute of an input image to be displayed, or automatically changed at every certain period.

6. The display apparatus of claim 1, wherein the 2-phase 4-pair emission clocks comprise:
a 1-A emission clock input to a first emission clock link line;
a 2-A emission clock input to a second emission clock link line adjacent to the first emission clock link line;
a 1-B emission clock input to a third emission clock link line adjacent to the second emission clock link line;
a 2-B emission clock input to a fourth emission clock link line adjacent to the third emission clock link line;
a 1-C emission clock input to a fifth emission clock link line adjacent to the fourth emission clock link line;
a 2-C emission clock input to a sixth emission clock link line adjacent to the fifth emission clock link line;
a 1-D emission clock input to a seventh emission clock link line adjacent to the sixth emission clock link line; and
a 2-D emission clock input to an eighth emission clock link line adjacent to the seventh emission clock link line.

7. The display apparatus of claim 4, wherein the 1-A emission clock, the 1-B emission clock, the 1-C emission clock, and the 1-D emission clock have a first phase, and
the 2-A emission clock, the 2-B emission clock, the 2-C emission clock, and the 2-D emission clock have a second phase which differs from the first phase.

8. The display apparatus of claim 5, wherein the first emission driver set comprises a first emission unit, a second emission unit, a third emission unit and a fourth emission unit, and
in the 2-phase mode, the first to fourth emission unit generate emission signals where phases thereof are sequentially delayed.

9. The display apparatus of claim 8, wherein the first to fourth emission units each receive one emission clock with the first phase and one emission clock with the second phase of the 2-phase 4-pair emission clocks from different emission clock link lines through corresponding first emission clock pair line of the plurality of first emission clock pair lines, and
each of the plurality of emission clock link lines supplies the emission clock input thereto to only one of the plurality of first emission clock pair lines.

10. The display apparatus of claim 5, wherein:
the first emission unit is connected to the first and sixth emission clock link lines through a 1-1 emission clock pair line and configured to receive the 1-A emission clock and the 2-C emission clock to drive an emission signal supply line of a first pixel row;
the second emission unit is connected to the second and fifth emission clock link lines through a 1-2 emission clock pair line and configured to receive the 2-A emission clock and the 1-C emission clock to drive an emission signal supply line of a second pixel row adjacent to the first pixel row;
the third emission unit is connected to the third and eighth emission clock link lines through a 1-3 emission clock pair line and configured to receive the 1-B emission clock and the 2-D emission clock to drive an emission signal supply line of a third pixel row adjacent to the second pixel row; and
the fourth emission unit is connected to the fourth and seventh emission clock link lines through a 1-4 emission clock pair line and configured to receive the 2-B emission clock and the 1-D emission clock to drive an emission signal supply line of a fourth pixel row adjacent to the third pixel row.

11. The display apparatus of claim 5, wherein the second emission driver set comprises a first emission unit, a second emission unit, a third emission unit and a fourth emission unit, and
in the 2-phase mode, the first to fourth emission unit generate emission signals where phases thereof are sequentially delayed.

12. The display apparatus of claim 11, wherein the first to fourth emission units each receive one emission clock with the first phase and one emission clock with the second phase of the 2-phase 4-pair emission clocks from different emission clock link lines through corresponding second emission clock pair line of the plurality of second emission clock pair lines, and
each of the plurality of emission clock link lines supplies the emission clock input thereto to only one of the plurality of second emission clock pair lines.

13. The display apparatus of claim 12, wherein:
the first emission unit is connected to the first and sixth emission clock link lines through a 2-1 emission clock pair line and configured to receive the 1-A emission clock and the 2-C emission clock to drive an emission signal supply line of a first pixel row;
the second emission unit is connected to the second and fifth emission clock link lines through a 2-2 emission clock pair line and configured to receive the 2-A emission clock and the 1-C emission clock to drive an emission signal supply line of a second pixel row adjacent to the first pixel row;
the third emission unit is connected to the third and eighth emission clock link lines through a 2-3 emission clock pair line and configured to receive the 1-B emission clock and the 2-D emission clock to drive an emission signal supply line of a third pixel row adjacent to the second pixel row; and
the fourth emission unit is connected to the fourth and seventh emission clock link lines through a 2-4 emission clock pair line and configured to receive the 2-B emission clock and the 1-D emission clock to drive an emission signal supply line of a fourth pixel row adjacent to the third pixel row.

14. The display apparatus of claim 1, wherein the 4-phase 4-pair emission clocks comprise:
a first emission clock input to a first emission clock link line;
a second emission clock input to the second emission clock link line adjacent to the first emission clock link line;
a third emission clock input to a third emission clock link line adjacent to the second emission clock link line;
a fourth emission clock input to a fourth emission clock link line adjacent to the third emission clock link line;
the fourth emission clock input to a fifth emission clock link line adjacent to the fourth emission clock link line;
the third emission clock input to a sixth emission clock link line adjacent to the fifth emission clock link line;
the second emission clock input to a seventh emission clock link line adjacent to the sixth emission clock link line; and
the first emission clock input to an eighth emission clock link line adjacent to the seventh emission clock link line.

15. The display apparatus of claim 14, wherein the first emission clock has a first phase, the second emission clock has a second phase which is later than the first phase, the third emission clock has a third phase which is later than the second phase, and the fourth emission clock has a fourth phase which is later than the third phase.

16. The display apparatus of claim 15, wherein the first emission driver set comprises a first emission unit, a second emission unit, a third emission unit and a fourth emission unit, and
in the 4-phase mode, the first to fourth emission unit generate emission signals where phases thereof are sequentially delayed.

17. The display apparatus of claim 15, wherein two emission units of the first to fourth emission units each receive one emission clock with the first phase and one emission clock with the second phase of the 4-phase 4-pair emission clocks from different emission clock link line through corresponding first emission clock pair line of the plurality of first emission clock pair lines,
the other two emission units of the first to fourth emission units each receive one emission clock with the second phase and one emission clock with the fourth phase of the 4-phase 4-pair emission clocks from different emission clock link line through corresponding first emission clock pair line of the plurality of first emission clock pair lines, and
each of the plurality of emission clock link lines supplies the emission clock input thereto to only one of the plurality of first emission clock pair lines.

18. The display apparatus of claim 17, wherein:
the first emission unit is connected to the first and sixth emission clock link lines through a 1-1 emission clock pair line and configured to receive the first emission clock and the third emission clock to drive an emission signal supply line of a first pixel row;
the second emission unit is connected to the second and fifth emission clock link lines through a 1-2 emission clock pair line and configured to receive the second emission clock and the fourth emission clock to drive an emission signal supply line of a second pixel row adjacent to the first pixel row;
the third emission unit is connected to the third and eighth emission clock link lines through a 1-3 emission clock pair line and configured to receive the third emission clock and the first emission clock to drive an emission signal supply line of a third pixel row adjacent to the second pixel row; and
the fourth emission unit is connected to the fourth and seventh emission clock link lines through a 1-4 emission clock pair line and configured to receive the fourth emission clock and the second emission clock to drive an emission signal supply line of a fourth pixel row adjacent to the third pixel row.

19. The display apparatus of claim 15, wherein the second emission driver set comprises a first emission unit, a second emission unit, a third emission unit and a fourth emission unit, and
in the 4-phase mode, the first to fourth emission unit generate emission signals where phases thereof are sequentially delayed.

20. The display apparatus of claim 19, wherein two emission units of the first to fourth emission units each receive one emission clock with the first phase and one emission clock with the second phase of the 4-phase 4-pair emission clocks from different emission clock link line through corresponding second emission clock pair line of the plurality of second emission clock pair lines,
the other two emission units of the first to fourth emission units each receive one emission clock with the second phase and one emission clock with the fourth phase of the 4-phase 4-pair emission clocks from different emission clock link line through corresponding second emission clock pair line of the plurality of second emission clock pair lines, and
each of the plurality of emission clock link lines supplies the emission clock input thereto to only one of the plurality of second emission clock pair lines.

21. The display apparatus of claim 20, wherein:
the first emission unit is connected to the first and sixth emission clock link lines through a 2-1 emission clock pair line and configured to receive the first emission clock and the third emission clock to drive an emission signal supply line of a first pixel row;
the second emission unit is connected to the second and fifth emission clock link lines through a 2-2 emission clock pair line and configured to receive the second emission clock and the fourth emission clock to drive an emission signal supply line of a second pixel row adjacent to the first pixel row;
the third emission unit is connected to the third and eighth emission clock link lines through a 2-3 emission clock pair line and configured to receive the third emission clock and the first emission clock to drive an emission signal supply line of a third pixel row adjacent to the second pixel row; and
the fourth emission unit is connected to the fourth and seventh emission clock link lines through a 2-4 emission clock pair line and configured to receive the fourth emission clock and the second emission clock to drive an emission signal supply line of a fourth pixel row adjacent to the third pixel row.

22. The display apparatus of claim 1, wherein emission units included in the first emission driver set and emission units included in the second emission driver set are axisymmetric with respect to a symmetric axis between the first emission driver set and the second emission driver set.
